(19) United States
(12) Patent Application Publication
(10) Pub. No.: US 2026/0020619 A1
(43) Pub. Date: Jan. 22, 2026

(54) AEROSOL GENERATION APPARATUS

(71) Applicant: YIBLA (USA) TECHNOLOGY CO., LTD, CITY OF INDUSTRY, CA (US)

(72) Inventors: Guangrui WANG, Puyang (CN); Yuanguo LIU, Shenzhen (CN); Aibing FAN, Shenzhen (CN); Jianjun QIU, Shenzhen (CN); Huihong LI, Shenzhen (CN)

(21) Appl. No.: 18/810,513

(22) Filed: Aug. 21, 2024

(30) Foreign Application Priority Data
Jul. 17, 2024 (CN) 202410964755.7

(51) Int. Cl. A24F 40/60; A24F 40/40; A24F 40/51; A24F 40/90; H05K 1/02; H05K 1/18; H05K 5/02

(52) U.S. Cl. CPC A24F 40/60; A24F 40/40; A24F 40/51; A24F 40/90; H05K 1/0274; H05K 1/189; H05K 5/02; H05K 2201/10106; H05K 2201/10121; H05K 2201/10128

(57) ABSTRACT

The present application is an aerosol generation apparatus, including a shell, an atomization core, an electric control assembly, and a flexible display module electrically connected to the electric control assembly, where the shell is internally provided with a gas flow passage and an accommodating compartment for accommodating an aerosol forming substance; the atomization core is mounted on a gas flow circulation path of the gas flow passage and is in communication with the accommodating compartment; the electric control assembly is mounted in the shell and is electrically connected to the atomization core; and the flexible display module is provided 360 degrees around the shell in a circumferential direction of the shell to cover outer surfaces of the shell. The aerosol generation apparatus disclosed in the present application has the advantage of large display area, so that more visual information can be displayed to a user.

### CROSS REFERENCE TO RELATED APPLICATIONS

The present application claims the priority of Chinese patent application No. 202410964755.7, filed on Jul. 17, 2024, and contents of which are incorporated herein by reference.

### TECHNICAL FIELD

The present application relates to the technical field of electronic atomization, in particular to an aerosol generation apparatus.

### BACKGROUND

An aerosol generation apparatus is an electronic device that can atomize aerosol forming substances such as tobacco tar and medical solutions stored therein into aerosols in an electric heating manner. The existing aerosol generation apparatus on the market usually includes structures such as an atomization core, a battery and an accommodating compartment, where the accommodating compartment generally accommodates the aerosol forming substances, and the aerosol forming substances in the accommodating compartment can be conducted to the atomization core under the capillary action; in a process that a user uses the aerosol generation apparatus for suction, the battery supplies electric energy to the atomization core, so that the atomization core can be electrified for heating; and heat generated by electrifying and heating of the atomization core can be used for atomizing the aerosol forming substances conducted to the atomization core into the aerosols that can be inhaled by the user.

With the continuous use of the aerosol generation apparatus, the battery capacity of the aerosol generation apparatus and the amount of the aerosol forming substances will be gradually reduced, and in order to facilitate the user to know the residual capacity of the aerosol generation apparatus and the residual amount of the aerosol forming substances directly at any time, the aerosol generation apparatus is usually externally equipped with a display screen that can display information such as the residual capacity and the residual amount of the aerosol forming substances. However, the existing aerosol generation apparatus with the display screen generally has the following problem:
the display screen used is usually a display screen with a rigid glass substrate, so that the display screen can usually only be mounted on one outer surface of the aerosol generation apparatus (such as a front surface, a back surface or a side surface of the aerosol generation apparatus), resulting in the problem of small display area of the aerosol generation apparatus; however, with the continuous development of an electronic atomization technology, the information that needs to be displayed on the display screen increases, so that how to increase the display area of the aerosol generation apparatus to enable the aerosol generation apparatus to display more information is an urgent technical problem to be solved by those skilled in the art.

### SUMMARY

The present application mainly aims to provide an aerosol generation apparatus, and aims to solve the technical problem of small display area of an existing aerosol generation apparatus with a display screen.

In order to achieve the above purposes, the present application provides an aerosol generation apparatus. The aerosol generation apparatus comprises:
a shell which is internally provided with a gas flow passage and an accommodating compartment for accommodating an aerosol forming substance;
an atomization core which is mounted on a gas flow circulation path of the gas flow passage and is in communication with the accommodating compartment;
an electric control assembly which is mounted in the shell and is electrically connected to the atomization core; and
a bendable flexible display module which is electrically connected to the electric control assembly, wherein the flexible display module is provided 360 degrees around the shell in a circumferential direction of the shell to cover a plurality of outer surfaces of the shell at different positions.

Compared with the prior art, the present application has the beneficial effects as follows:
in the technical solution of the present application, the bendable flexible display module is used to display related parameter information of the aerosol generation apparatus, and the flexible display module covers the plurality of outer surfaces of the shell at the different positions in a 360-degree surrounding manner in the circumferential direction of the shell of the aerosol generation apparatus by means of the bendable characteristic of the flexible display module, so that display regions of the flexible display module can be distributed on the plurality of outer surfaces at the different positions in the circumferential direction of the shell, and 360-degree all-around information display can be achieved; therefore, compared with a traditional aerosol generation apparatus with only one outer surface covered with a display screen, the aerosol generation apparatus provided in the present application has the larger display area and can display more visual information to a user.

### BRIEF DESCRIPTION OF THE DRAWINGS

In order to explain embodiments of the present application or technical solutions in the prior art more clearly, drawings needed in descriptions of the embodiments or the prior art will be briefly introduced below. Obviously, the drawings in the following descriptions are only some embodiments of the present application, and for a person of ordinary skill in the art, other drawings can be obtained according to structures shown in these drawings without involving any inventive effort.

FIG. 1 is a three-dimensional structural schematic diagram of an aerosol generation apparatus in an embodiment of the present application;

FIG. 2 is a sectional view of an aerosol generation apparatus in an embodiment of the present application;

FIG. 3 is a partial enlarged schematic diagram at A in FIG. 2;

FIG. 4 is a structural breakdown schematic diagram of FIG. 1;

FIG. 5 is a three-dimensional structural schematic diagram of an aerosol generation apparatus in an embodiment of the present application after an annular protective shell is removed;

FIG. 6 is a three-dimensional structural schematic diagram of FIG. 5 after a flexible display module is removed;

FIG. 7 is a three-dimensional structural schematic diagram of a flexible display module enclosing an annular structure in an embodiment of the present application;

FIG. 8 is a planar schematic diagram of FIG. 7 after expansion;

FIG. 9 is a sectional view of a flexible display module in an embodiment of the present application;

FIG. 10 is a sectional view of a flexible display module in another embodiment of the present application;

FIG. 11 is a planar schematic diagram of a flexible display film in an embodiment of the present application;

FIG. 12 is a front schematic diagram of a flexible printed circuit board connected to a flexible flat cable in an embodiment of the present application;

FIG. 13 is a back schematic diagram of a flexible printed circuit board in an embodiment of the present application;

FIG. 14 is a front schematic diagram of a flexible printed circuit board in another embodiment of the present application;

FIG. 15 is a structural schematic diagram of an aerosol generation apparatus in another embodiment of the present application; and

FIG. 16 is a structural schematic diagram of an aerosol generation apparatus in another embodiment of the present application.

### DESCRIPTION OF REFERENCE NUMERALS

1—shell, 10—body shell, 101—first protrusion, 102—second protrusion, 11—bottom cover, 110—first end surface, 111—first annular fence portion, 12—top cover, 120—second end surface, 121—second annular fence portion, 13—annular surface, 130—annular mounting groove, and 131—side surface;
2—atomization core;
3—electric control assembly, 31—power supply, and 32—control circuit board;
4—flexible display module, 401—first edge, 4011—first notch, 402—second edge, 4021—second notch, 403—third notch, 41—flexible display film, 411—light-transmitting region, 412—light-shielding region, 42—flexible diffusion film, 43—flexible light-shielding film, 431—light-transmitting hole, 44—flexible light-reflecting layer, 45—light-emitting element, 46—flexible printed circuit board, 461—first mounting region, 462—second mounting region, 463—circuit trajectory, 47—current driving element, 48—current input interface, and 49—test point;
5—gas flow passage, 51—gas inlet, and 52—gas outlet;
6—accommodating compartment;
7—annular protective shell;
81—suction nozzle, 82—charging interface, and 83—gas flow sensor;
91—metal sheet, 910—positioning hole, and 92—flexible flat cable.

The achievement of the purpose, functional characteristics and advantages of the present application will be further explained with reference to the accompanying drawings in conjunction with the embodiments.

### DETAILED DESCRIPTION OF EMBODIMENTS

The technical solutions in embodiments of the present application will be described clearly and completely below in conjunction with the accompanying drawings in the embodiments of the present application. Obviously, the described embodiments are only a part of embodiments of the present application, not all of them. On the basis of the embodiments of the present application, all other embodiments obtained by those of ordinary skill in the art without involving any inventive effort should fall within the scope of protection of the present application.

It should be noted that if the embodiments of the present application involve directional indications (such as up, down, left, right, front, back, etc.), the directional indications are only used to explain the relative position relationship and motions of components in a specific attitude, and if the specific attitude is changed, the directional indications will be changed accordingly.

In addition, if the embodiments of the present application include descriptions involving “first”, “second” and the like, the descriptions involving “first”, “second” and the like are only for description purposes, and cannot be understood as indicating or implying the relative importance or implicitly indicating the number of indicated technical features. Thus, the features defined as “first” and “second” can explicitly or implicitly include at least one such feature. In addition, if “and/or” appears in the full text, its meanings include three parallel solutions, for example, “A and/or B” includes solution A, or solution B, or a solution satisfying A and B at the same time. Besides, the technical solutions of the embodiments can be combined with one another on the basis that such combinations can be implemented by a person of ordinary skill in the art, and when the combinations of the technical solutions are contradictory or cannot be implemented, it should be considered that such combinations of the technical solutions do not exist and do not fall within the scope of protection claimed by the present application.

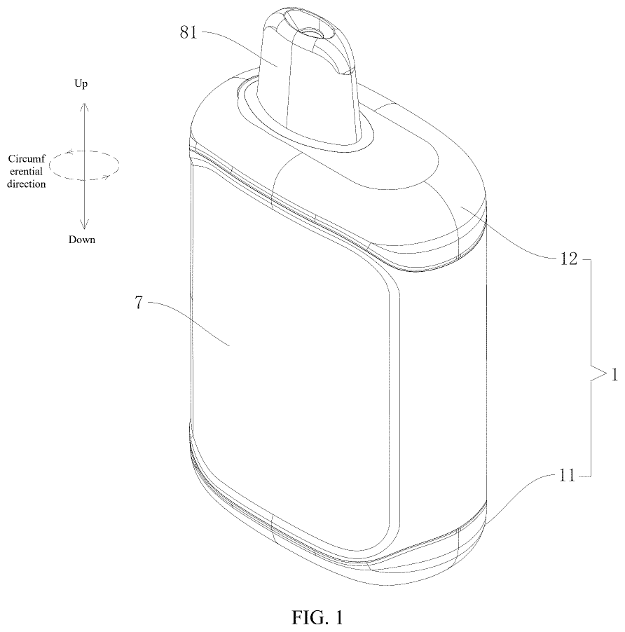

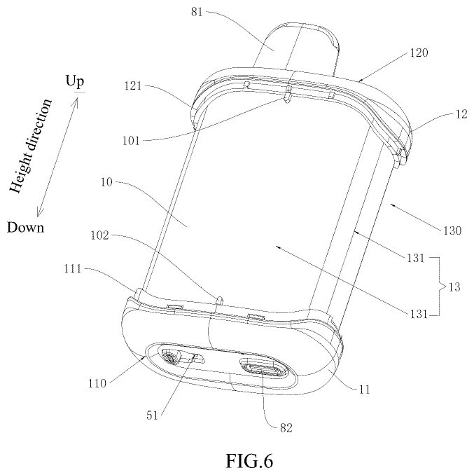

Reference is made to FIGS. 1-7 and FIGS. 15-16. An embodiment of the present application provides an aerosol generation apparatus, the aerosol generation apparatus including a shell 1, an atomization core 2, an electric control assembly 3 and a bendable flexible display module 4, where the shell 1 is internally provided with a gas flow passage 5 and an accommodating compartment 6 for accommodating an aerosol forming substance, and the aerosol forming substance may be substances such as tobacco tar and medical solutions, which can be determined according to the actual use requirements of a user and is not specifically limited in this embodiment.

The atomization core 2 is mounted on a gas flow circulation path of the gas flow passage 5, so that an aerosol generated by the atomization core 2 can be taken away by a gas flow formed in the gas flow passage 5 and discharged to the outside for suction of the user. In addition, the atomization core 2 is in communication with the accommodating compartment 6, so that the atomization core 2 can suck the aerosol forming substance from the accommodating compartment 6 for heating and atomization. It should be noted here that the specific structural composition and working principle of the atomization core 2 and the communication manner between the atomization core 2 and the accommodating compartment 6 are well known to those skilled in the art and are not repeated here.

The flexible display module 4 is provided 360 degrees around the shell 1 in a circumferential direction of the shell 1 and covers a plurality of outer surfaces of the shell 1 at different positions, and the flexible display module 4 is mainly configured to display related parameter information of the aerosol generation apparatus, for example, the residual capacity of the aerosol generation apparatus, the residual amount of the aerosol forming substance, the working power, and preset pattern information. In some optional implementation manners, the flexible display module 4 can be in the structural form of a flexible display screen, for example, a flexible OLED screen and a flexible LCD screen, and the flexible display module 4 can be fixed to the plurality of outer surfaces of the shell 1 in the circumferential direction thereof through bonding and snap-fitting. It is understandable here that after the flexible display module 4 is provided 360 degrees around the shell 1 in the circumferential direction of the shell 1, the entire flexible display module 4 can be of an annular structure, for example, an approximately “O”-shaped annular structure, a racetrack-shaped annular structure and a rectangular annular structure, which is not specifically limited in this embodiment, and generally, the shape shown after enclosing of the flexible display module 4 is determined by the shapes of the outer surfaces of the shell 1 in the circumferential direction thereof. In addition, it should be noted here that the 360-degree surrounding in this embodiment is not the absolute 360 degrees, and a certain mounting error is allowed. Specifically, after the flexible display module 4 is mounted on the outer surfaces of the shell 1 in a 360-degree surrounding manner in the circumferential direction of the shell 1, the spacing between two ends of the flexible display module 4 in a bending length direction thereof being 0-0.5 mm can be regarded as the 360-degree surrounding arrangement manner.

The electric control assembly 3 is mounted in the shell 1, the electric control assembly 3 is electrically connected to the atomization core 2 and the flexible display module 4 respectively, and the electric control assembly 3 is mainly configured to control the flexible display module 4 to display the related parameter information of the aerosol generation apparatus and to control the working state of the atomization core 2, for example, to control the atomization core 2 to work as per preset power or to control the atomization core 2 to be powered off to stop working. In some optional implementation manners, the electric control assembly 3 specifically includes a power supply 31 for supplying electric energy and a control circuit board 32 having a control function, the control circuit board 32 is electrically connected to the atomization core 2, the flexible display module 4 and the power supply 31 respectively, the power supply 31 can be a dry battery or a lithium battery, and the control circuit board 32 can be specifically in the structural form of a device having the control function, such as a single-chip microcomputer, a processor and a controller.

In the technical solution of this embodiment, the bendable flexible display module 4 is used to display the related parameter information of the aerosol generation apparatus, and the flexible display module 4 covers the plurality of outer surfaces of the shell 1 at the different positions in the 360-degree surrounding manner in the circumferential direction of the shell 1 of the aerosol generation apparatus by means of the bendable characteristic of the flexible display module 4, so that display regions of the flexible display module 4 can be distributed on the plurality of outer surfaces at the different positions in the circumferential direction of the shell 1, and 360-degree all-around information display can be achieved; therefore, compared with a traditional aerosol generation apparatus with only one outer surface covered with a display screen, the aerosol generation apparatus provided in this embodiment has the larger display area and can display more visual information to a user.

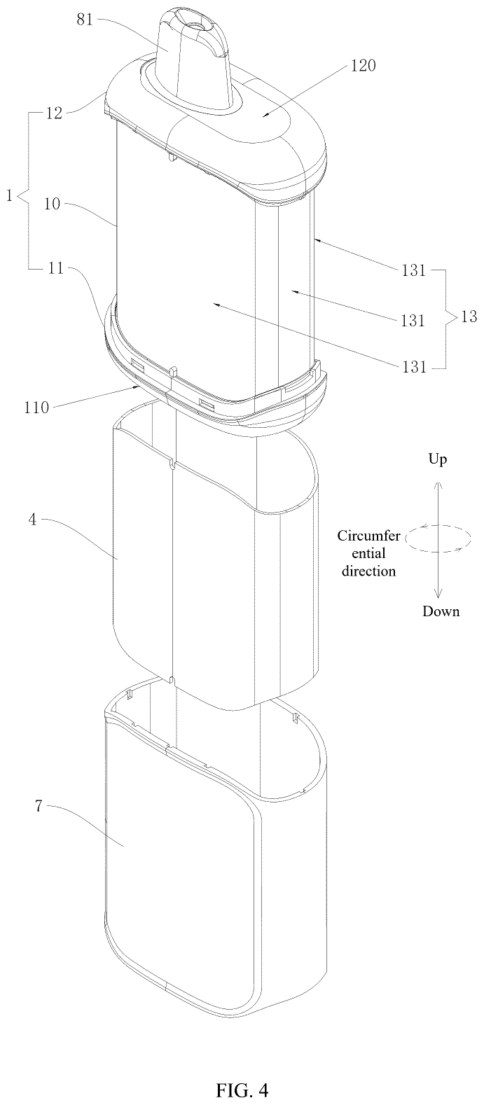

Reference is made to FIGS. 4-7. In some optional embodiments of the present application, the shell 1 has a first end surface 110 and a second end surface 120 which are opposite to each other in a height direction thereof, the shell 1 has an annular surface 13 located between the first end surface 110 and the second end surface 120 in the circumferential direction thereof, the flexible display module 4 is provided on the annular surface 13 in a 360-degree surrounding manner in the circumferential direction of the shell 1, the annular surface 13 includes a plurality of side surfaces 131 sequentially connected end-to-end into a whole in the circumferential direction of the shell 1, and a joint between the two adjacent side surfaces 131 is in smooth transition. Specifically, the two adjacent side surfaces 131 can be in smooth transition in a rounded manner.

In this embodiment, it should be noted that each side surface 131 of the annular surface 13 can be a cambered surface or a plane, which is not specifically limited in this embodiment. In this embodiment, the smooth transition design is performed on the joint between the two adjacent side surfaces 131, and compared with the situation that the joint between the two adjacent side surfaces 131 is an edge, such arrangement can avoid the situation that obvious folds appear at the joint between the two adjacent side surfaces 131 after the flexible display module 4 is fixed to the plurality of side surfaces 131, thereby reducing the risk of affecting the display effect of the flexible display module 4 due to the obvious folds of the flexible display module 4.

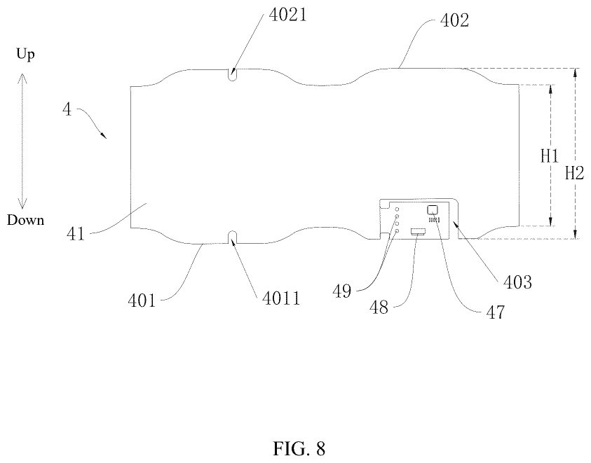

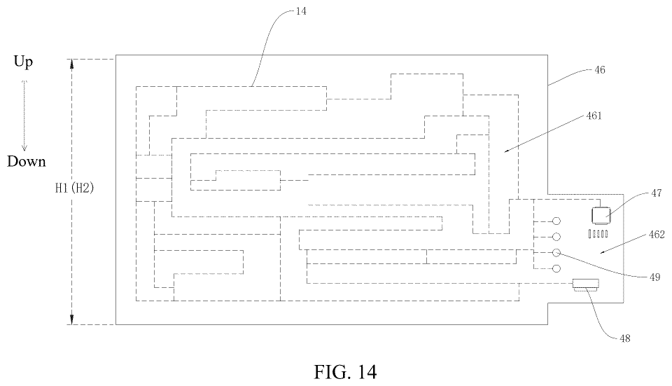

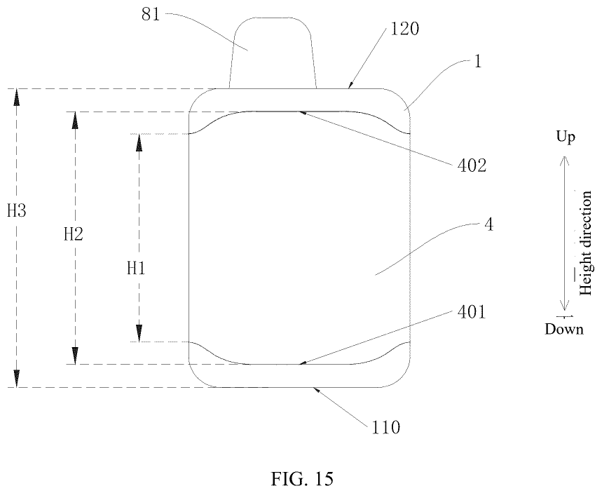

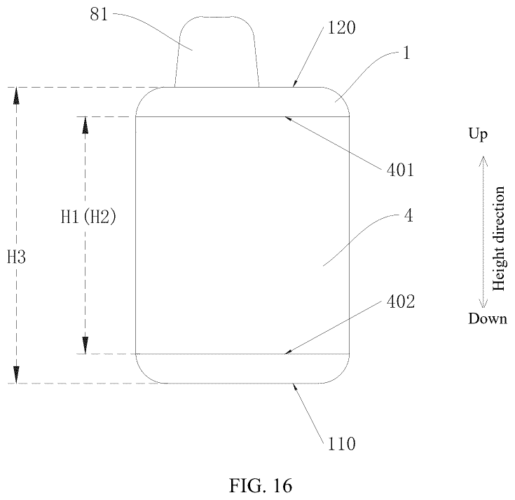

Reference is made to FIGS. 15-16. In some optional embodiments of the present application, in the height direction of the shell 1, the flexible display module 4 has a first edge 401 and a second edge 402 which are opposite to each other, assuming that a minimum vertical height between the first edge 401 and the second edge 402 is H1, a maximum vertical height between the first edge 401 and the second edge 402 is H2, and a vertical height between the first end surface 110 and the second end surface 120 is H3, 0.5H3≤H1≤0.9H3, and 0.5H3≤H2≤0.9H3, for example, assuming that H3 is 70 mm, H1 can be 35 mm, 40 mm, 50 mm, 55 mm, 63 mm, and the like, and H2 can be 35 mm, 40 mm, 50 mm, 55 mm, 63 mm, and the like. It should be noted here that when the flexible display module 4 is in a non-enclosing expanded state, extension trajectories of the first edge 401 and the second edge 402 can be horizontal straight lines, or a plurality of uneven arc lines, or a plurality of uneven broken lines (the broken lines can be horizontal lines, arc lines, inclined lines, and the like), and of course, they can be in other shapes, which are not specifically limited in this embodiment. In this embodiment, it is understandable that when the flexible display module 4 is in the non-enclosing expanded state, if the display region of the flexible display module 4 is a rectangle (as shown in FIG. 14 and FIG. 16), H1=H2; and when the flexible display module 4 is in the non-enclosing expanded state, if the display region of the flexible display module 4 is an irregular pattern (as shown in FIG. 8 and FIG. 15), H1<H2.

In this embodiment, on the basis of the above structural design, on one hand, the minimum vertical height between the first edge 401 and the second edge 402 of the flexible display module 4 is set to be 0.5-0.9 times the vertical height between the first end surface 110 and the second end surface 120 of the shell 1, so that the flexible display module 4 can at least cover a half of the surface area of the annular surface 13 of the shell 1 or more, thereby ensuring that the aerosol generation apparatus has the large display area for displaying the information; on the other hand, the maximum vertical height between the first edge 401 and the second edge 402 of the flexible display module 4 is set to be 0.5-0.9 times the vertical height between the first end surface 110 and the second end surface 120 of the shell 1, so that the situation that the difficulty in mounting the flexible display module 4 on the outer surfaces of the shell 1 is increased due to the excessively large surface area of the flexible display module 4 can be avoided, for example, when the joints between the annular surface 13 and the first end surface 110 and the second end surface 120 are arc surfaces in smooth transition, if the surface area of the flexible display module 4 is too large, when the flexible display module 4 is mounted on the annular surface 13 of the shell 1, it is difficult for the flexible display module 4 to cover these arc surfaces, and even the arc surfaces can be covered, folds appear easily at the joint between the annular surface 13 and the first end surface 110 or the joint between the annular surface 13 and the second end surface 120 for the flexible display module 4. It should be noted here that during specific implementation, in order to improve the appearance attractiveness of the aerosol generation apparatus, the flexible display module 4 can be arranged in the middle of the annular surface 13 in the surrounding manner as much as possible.

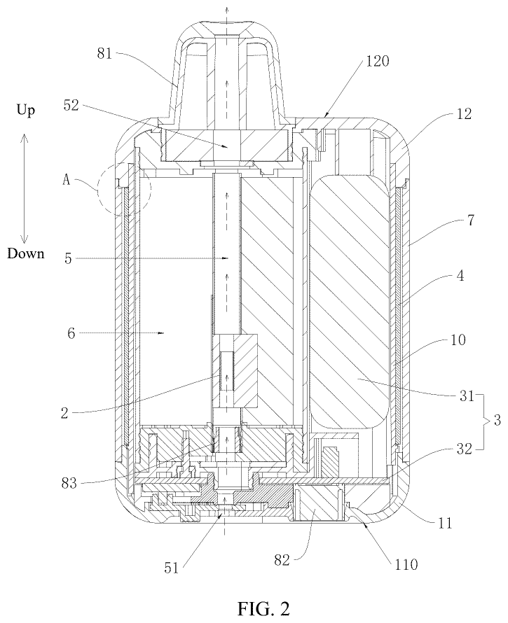

Reference is made to FIGS. 1-2. In some optional embodiments of the present application, the aerosol generation apparatus further includes a suction nozzle 81 provided on the second end surface 120 of the shell 1 in a protruding manner, the gas flow passage 5 has a gas inlet 51 and a gas outlet 52, the gas inlet 51 of the gas flow passage 5 is provided on the first end surface 110 of the shell 1, and the gas outlet 52 of the gas flow passage 5 is in communication with the suction nozzle 81. In this embodiment, the suction nozzle 81 is provided, so that the user can conveniently use the aerosol generation apparatus in a suction manner. Specifically, when the user bites the suction nozzle 81 for suction, the external air can enter the gas flow passage 5 through the gas inlet 51 of the gas flow passage 5 and form a suction gas flow, the suction gas flow takes away the aerosol generated by the atomization core 2 when flowing through the atomization core 2, and the aerosol finally flows out of the suction nozzle 81 with the suction gas flow to enter the mouth of the user to be inhaled by the user.

Reference is made to FIG. 2. In some optional embodiments of the present application, the aerosol generation apparatus further includes a charging interface 82 provided on the first end surface 110, where the charging interface 82 is electrically connected to the control circuit board 32 of the electric control assembly 3. Through such arrangement, when the capacity of the power supply 31 of the electric control assembly 3 is low or exhausted, the user can charge the aerosol generation apparatus conveniently.

Reference is made to FIG. 2. In some optional embodiments, the aerosol generation apparatus further includes a gas flow sensor 83 electrically connected to the control circuit board 32 of the electric control assembly 3, where the gas flow sensor 83 is located on the gas flow circulation path of the gas flow passage 5; and the control circuit board 32 of the electric control assembly 3 is configured to respond to a suction signal sent by the gas flow sensor 83 to control the atomization core 2 to be electrified to work and to control the flexible display module 4 to display preset information. In this embodiment, through arrangement of the gas flow sensor 83, the aerosol generation apparatus can work more intelligently, thereby improving the use experience of the user. Specifically, when the user bites the suction nozzle 81 for suction, the suction gas flow can be formed on the gas flow circulation path of the gas flow passage 5, and the suction gas flow can trigger the gas flow sensor 83 to act, so that the gas flow sensor 83 can send the suction signal representing that the user is sucking to the control circuit board 32; when the control circuit board 32 receives the suction signal, the control circuit board 32 controls the atomization core 2 to be electrified to work, the atomization core 2 is electrified to generate heat to atomize the aerosol forming substance sucked from the accommodating compartment 6 into the aerosol that can be inhaled by the user, and at the same time, the control circuit board 32 controls the flexible display module 4 to display the corresponding information, for example, the residual capacity of the aerosol generation apparatus, the residual amount of the aerosol forming substance, the working power, and preset pattern information. After the user stops suction, the gas flow sensor 83 can send a stop signal representing that the user stops suction to the control circuit board 32; when the control circuit board 32 receives the stop signal, the control circuit board 32 controls the atomization core 2 to be powered off to stop working, and at the same time, the control circuit board 32 can control the flexible display module 4 to stop working after a preset time, so that the user has a sufficient time interval to check the related information displayed by the flexible display module 4 after completing suction, where the preset time can be determined according to the actual use requirements, for example, it can be 3 s, 5 s, 6 s, 10 s, and the like.

In some optional embodiments of the present application, the flexible display module 4 can be in the structural form of the flexible display screen, and the flexible display module 4 can also be in the following structural form.

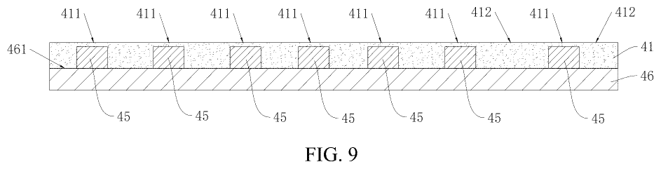

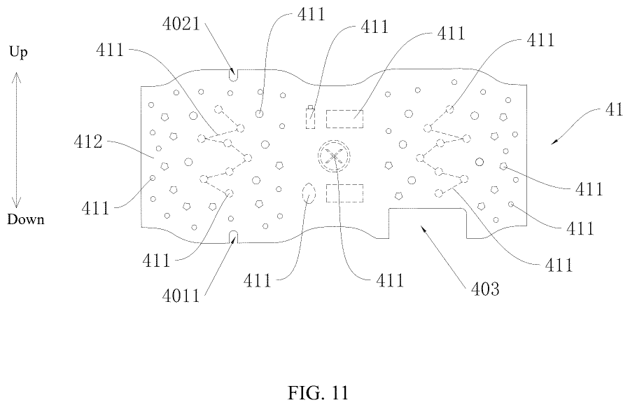

Specifically, reference is made to FIGS. 8-9 and FIG. 11. The flexible display module 4 includes a flexible display film 41, a flexible printed circuit board 46 with a circuit trajectory 463, and a plurality of light-emitting elements 45; the flexible printed circuit board 46 is provided on the annular surface 13 of the shell 1 in a 360-degree surrounding manner in the circumferential direction of the shell 1; the plurality of light-emitting elements 45 are distributed at intervals on a side surface 131 of the flexible printed circuit board 46 facing away from the annular surface 13 and are electrically connected to the circuit trajectory 463 of the flexible printed circuit board 46; the circuit trajectory 463 of the flexible printed circuit board 46 is electrically connected to the control circuit board 32 of the electric control assembly 3; and the flexible display film 41 is fixedly stacked on the side surface 131 of the flexible printed circuit board 46 facing away from the annular surface 13 and covers the light-emitting elements 45, the flexible display film 41 has a plurality of light-transmitting regions 411, each of the light-transmitting regions 411 is provided opposite to at least one of the light-emitting elements 45, and a region of the flexible display film 41 apart from the light-transmitting regions 411 is a light-shielding region 412.

In this embodiment, it is understandable that the flexible printed circuit board 46 is also called an FPC (flexible printed circuit) board, is a flexible circuit board printed with the circuit trajectory 463, and has the advantages of good flexibility, light weight and small thickness, in a specific manufacturing technology, the needed flexible printed circuit board 46 can be obtained by printing the circuit trajectory 463 on a flexible film, and the flexible film can be a polymer material having the high performance (such as the excellent heat resistance, chemical stability and bendability), for example, a polyimide film and a polyester film. In addition, it is also understandable that the flexible printed circuit board 46 can serve as a mounting carrier for the plurality of light-emitting elements 45, the circuit trajectory 463 on the flexible printed circuit board 46 can serve as a medium for electrically connecting the plurality of light-emitting elements 45 to the electric control assembly 3, and when the plurality of light-emitting elements 45 are connected to the power supply 31 of the electric control assembly 3 by means of the circuit trajectory 463 of the flexible printed circuit board 46, the plurality of light-emitting elements 45 can be electrified to emit light.

In this embodiment, it should be noted that during specific implementation, the light-emitting elements 45 can be components that can be electrified to emit light, such as LED lamp beads. In some optional implementation manners, the light-emitting elements 45 can be LED lamp beads with dimensions being 0.5-1.5 mm in length, 0.2-0.8 mm in width and 0.1-0.8 mm in thickness. Preferably, the light-emitting elements 45 can specifically be LED lamp beads in the model of 0402, and the LED lamp beads in such model have the dimensions being 1.0 mm in length, 0.5 mm in width and 0.4 mm in thickness; and through repeated tests, when the flexible display module 4 provided in this embodiment uses the LED lamp beads in such model as the light-emitting elements 45, compared with LED lamp beads in other dimensions, the flexible display module 4 can obtain the better display effect and the high quality reliability. The light-emitting elements 45 can be fixed to the surface of the flexible printed circuit board 46 through welding and bonding (for example, bonding by means of insulating glue or conductive glue), and be electrically connected to the circuit trajectory 463 of the flexible printed circuit board 46.

In this embodiment, it should be noted that during specific implementation, the flexible display film 41 can be made of flexible materials such as polyimide (PI), polyethylene glycol terephthalate (PET), polyethylene naphthalate (PEN), liquid crystal polymers (LCP), polyvinyl alcohol (PVA) and polydimethylsiloxane (PDMS), all that is required is to meet use requirements, and the specific material of the flexible display film 41 is not specifically limited in this embodiment. When the flexible display film 41 is made of the transparent flexible material, the light-transmitting regions 411 and the light-shielding region 412 can be formed on the flexible display film 41 through coating of light-shielding ink, for example, when the flexible display film 41 is the transparent polyimide film, a surface of the polyimide film can be coated with the light-shielding ink in a preset manner, a region coated with the light-shielding ink in the polyimide film can be regarded as the light-shielding region 412 of the flexible display film 41, and regions that are not coated with the light-shielding ink in the polyimide film can be regarded as the light-transmitting regions 411 of the flexible display film 41. Moreover, when the flexible display film 41 is made of the opaque flexible material, the light-transmitting regions 411 and the light-shielding region 412 can be formed on the flexible display film 41 through laser engraving, for example, when the flexible display film 41 is the opaque PET film, the needed light-transmitting regions 411 can be engraved on a surface of the PET film through laser engraving (the light-transmitting regions 411 at this time are essentially through holes), and a region that is not engraved in the PET film forms the light-shielding region 412. Of course, the light-transmitting regions 411 and the light-shielding region 412 on the flexible display film 41 can also be obtained in other mature manners in the art, which are not specifically limited in this embodiment. It should also be noted here that during specific implementation, the shapes, sizes and position distribution of the light-transmitting regions 411 can be determined according to the actual use requirements, and are not specifically limited in this embodiment. Optionally, the light-transmitting regions 411 can be in shapes of characters, numbers, letters, dots and lines, and when the light emitted by the light-emitting elements 45 reaches the light-transmitting regions 411, light display information in the corresponding shapes can be displayed, for example, when the light emitted by the light-emitting elements 45 reaches the light-transmitting regions 411 in the shapes of letters, the user can observe light-emitting letters on the surface of the flexible display film 41, so that the light display information in multiple different shapes can be obtained by combining the plurality of light-transmitting regions 411 in different shapes. Thus, various information (such as the residual capacity, the working power, the residual amount of the aerosol forming substance and the preset patterns) of the aerosol generation apparatus can be represented by combining the light display information in the different shapes. In addition, the number of the light-emitting elements 45 corresponding to each light-transmitting region 411 can also be determined according to the actual use requirements, and is also not specifically limited in this embodiment.

In this embodiment, it should also be noted that during specific implementation, the flexible display film 41 can be fixedly stacked on the surface of the flexible printed circuit board 46 provided with the light-emitting elements 45 by means of the glue (the glue can be a double-faced adhesive tape, a structural adhesive and an optical transparent adhesive), and similarly, the side surface 131 of the flexible printed circuit board 46 facing away from the flexible display film 41 can also be fixed to the annular surface 13 of the shell 1 by means of the glue.

In this embodiment, on the basis of the above structural design, after the plurality of light-emitting elements 45 are connected to the power supply 31 of the electric control assembly 3 by means of the circuit trajectory 463 of the flexible printed circuit board 46, the plurality of light-emitting elements 45 are electrified to emit light, and the light emitted can be displayed in the light-transmitting regions 411 of the flexible display film 41, that is, the light-transmitting regions 411 of the flexible display film 41 can serve as a light display region of the flexible display module 4, thereby achieving the display function of the flexible display module 4. In addition, the flexible display film 41 and the flexible printed circuit board 46 are of flexible structures, so that the display module formed by stacking the flexible display film 41 and the flexible printed circuit board 46 is also of a flexible structure, and the flexible display module 4 has the bendable characteristic. In addition, the flexible display module 4 provided in this embodiment has the advantages of simple structure and low manufacturing cost.

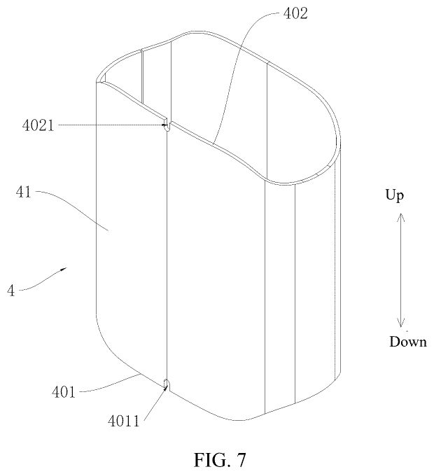

Further, reference is made to FIGS. 7-8 and FIG. 12. In some optional embodiments, the flexible display module 4 further includes a current driving element 47 and a current input interface 48, a side surface 131 of the flexible printed circuit board 46 facing the flexible display film 41 has a first mounting region 461 and a second mounting region 462 which are connected to each other, the area of the first mounting region 461 is greater than that of the second mounting region 462, the second mounting region 462 is provided on an edge of the flexible printed circuit board 46, the plurality of light-emitting elements 45 are fixed in the first mounting region 461, and the current driving element 47 and the current input interface 48 are mounted in the second mounting region 462 at an interval and are electrically connected to the circuit trajectory 463 of the flexible printed circuit board 46.

In this embodiment, by providing the current input interface 48 electrically connected to the circuit trajectory 463 of the flexible printed circuit board 46, the light-emitting elements 45 of the flexible display module 4 can be conveniently electrically connected to the control circuit board 32 of the electric control assembly 3, for example, during specific application, all that is required is to connect one end of one wire to the current input interface 48 and connect the other end of the wire to the control circuit board, thus the electrical connection between the light-emitting elements 45 and the electric control assembly 3 can be quickly achieved, and the operation is very convenient. The current input interface 48 can be in the structural form of a socket type connector and can also be communication interfaces in other types, all that is required is to meet the use requirements, and it is not specifically limited in this embodiment.

In this embodiment, by providing the current driving element 47 electrically connected to the circuit trajectory 463 of the flexible printed circuit board 46, after the electric control assembly 3 is connected by means of the current input interface 48, the light-emitting elements 45 can be conveniently driven by the control circuit board 32 of the electric control assembly 3 to emit light in the preset manner so as to display needed information on the flexible display film 41. It should be noted here that during specific implementation, the current driving element 47 can be a universal driving chip in the art, and the specific structure and use principle thereof are well-known to those skilled in the art and are therefore not repeated here.

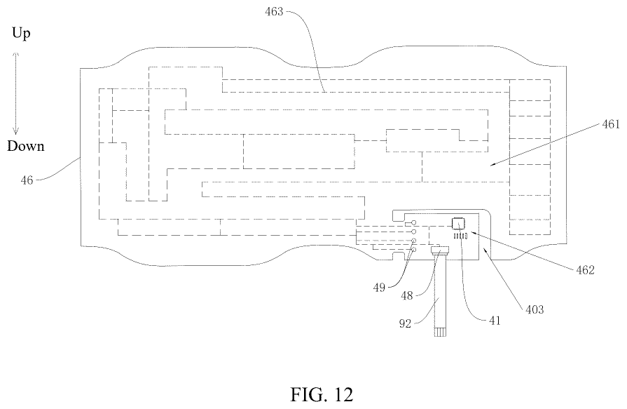

In this embodiment, it should be noted that when the flexible printed circuit board 46 is a strip-shaped sheet having a certain length and width, the second mounting region 462 can be provided on a length edge (as shown in FIG. 12) or a width edge (as shown in FIG. 14) of the flexible printed circuit board 46.

Further, reference is made to FIG. 8 and FIGS. 11-12. In some optional embodiments of the present application, a third notch 403 is formed in an edge of the entire flexible display module 4, a portion of the flexible printed circuit board 46 provided with the second mounting region 462 is located inside the third notch 403, and a region of the side surface 131 of the flexible printed circuit board 46 facing the flexible display film 41, apart from the second mounting region 462, is the first mounting region 461. Compared with the arrangement manner of providing the second mounting region 462 of the flexible printed circuit board 46 on the width edge of the flexible printed circuit board 46 in a protruding manner (as shown in FIG. 14), such arrangement can prevent the influence on the display effect of the flexible display module 4 due to the fact that the portion of the flexible printed circuit board 46 provided with the second mounting region 462 overlaps with the light-transmitting regions 411 of the flexible display film 41 in the process of mounting the flexible display module 4 on the annular surface 13 of the shell 1 in the 360-degree surrounding manner in the circumferential direction of the shell 1. Compared with the arrangement manner of providing the second mounting region 462 of the flexible printed circuit board 46 on the length edge of the flexible printed circuit board 46 in a protruding manner, such arrangement can prevent the situation that the display area of the aerosol generation apparatus in the height direction thereof cannot be increased to the maximum extent due to the fact that the portion of the flexible printed circuit board 46 provided with the second mounting region 462 occupies too much space in the height direction of the shell 1 in the process of mounting the flexible display module 4 on the annular surface 13 of the shell 1 in the 360-degree surrounding manner in the circumferential direction of the shell 1. Specifically, in the technical solution provided in this embodiment, an avoidance design is performed on the portion of the flexible printed circuit board 46 provided with the second mounting region 462, that is, the portion of the flexible printed circuit board 46 provided with the second mounting region 462 is located inside the third notch 403 formed in the edge of the entire flexible display module 4, thus in the process of mounting the flexible display module 4 on the annular surface 13 of the shell 1 in the 360-degree surrounding manner in the circumferential direction of the shell 1, the flexible display module 4 can conveniently enclose a complete annular structure, the portion of the flexible printed circuit board 46 provided with the second mounting region 462 cannot overlap with the light-transmitting regions 411 of the flexible display film 41, and the portion of the flexible printed circuit board 46 provided with the second mounting region 462 cannot occupy the extra space in the height direction of the shell 1, thereby improving the mounting convenience of the flexible display module 4 on the premise of ensuring the display area and display effect of the flexible display module 4.

In this embodiment, it should be noted that in some specific application scenes, when the flexible display module 4 is a strip-shaped sheet having a certain length and width, the third notch 403 can be formed in the length edge of the flexible display module 4 (as shown in FIG. 8), and the third notch 403 can also be formed in the width edge of the flexible display module 4, which is not specifically limited in this embodiment.

Further, reference is made to FIG. 8 and FIG. 12. In some optional embodiments of the present application, a plurality of test points 49 made of metal materials are further provided on the second mounting region 462 of the flexible printed circuit board 46 in an exposed manner, and the plurality of test points 49 are electrically connected to the circuit trajectory 463 of the flexible printed circuit board 46. Thus, by providing the plurality of test points 49 made of the metal materials, a tester can conveniently perform corresponding function tests or fault tests on the flexible display module 4.

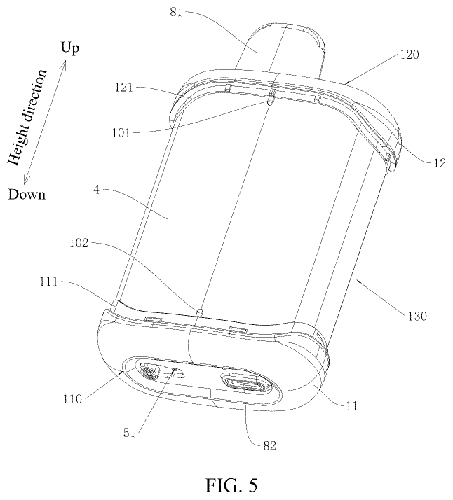

Further, reference is made to FIG. 2, FIGS. 5-8 and FIG. 12. In some optional embodiments of the present application, the aerosol generation apparatus further includes a flexible flat cable 92, where one end of the flexible flat cable 92 is inserted into the current input interface 48, and the other end of the flexible flat cable 92 is inserted into the electric control assembly 3. Specifically, the control circuit board 32 of the electric control assembly 3 is provided with a current output interface (not shown), one end of the flexible flat cable 92 is inserted into the current input interface 48, and the other end of the flexible flat cable 92 is inserted into the current output interface, where the current output interface on the control circuit board 32 can be in the same interface type as the current input interface 48 on the flexible display module 4. Through such arrangement, after the flexible display module 4 is mounted on the annular surface 13 of the shell 1 in the 360-degree surrounding manner in the circumferential direction of the shell 1, a mounting person is only required to insert the two ends of the flexible flat cable 92 into the current input interface 48 and the current output interface, thus the reliable electrical connection between the flexible display module 4 and the electric control assembly 3 can be quickly completed, and the operation is very convenient. During specific implementation, in order to shorten the length of the flexible flat cable 92 used and to further improve the convenience in electrical connection between the flexible display module 4 and the electric control assembly 3, the third notch 403 can be formed in the length edge on a lower side of the flexible display module 4, at the same time, an opening corresponding to the third notch 403 can be formed in the annular surface 13 of the shell 1 (the opening can be provided opposite to the third notch 403 and can also be provided below the third notch 403), and the current output interface of the control circuit board 32 is provided adjacent to the opening and opposite to the opening.

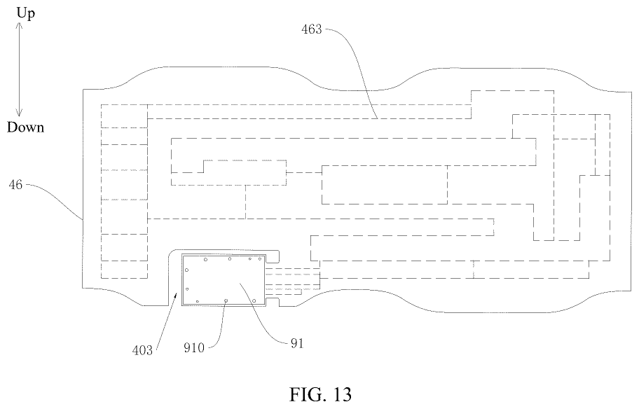

Reference is made to FIGS. 12-13. In some optional embodiments of the present application, the aerosol generation apparatus further includes a metal sheet 91, where the metal sheet 91 is fixed to one side of the flexible printed circuit board 46 facing away from the second mounting region 462. In this embodiment, the metal sheet 91 can reinforce (that is, enhance the strength) the portion of the flexible printed circuit board 46 including the second mounting region 462, so that in the process of mounting the flexible display module 4 on the annular surface 13 of the shell 1 in the 360-degree surrounding manner in the circumferential direction of the shell 1, the portion of the flexible printed circuit board 46 where the current driving element 47 and the current input interface 48 are mounted can be conveniently positioned on the annular surface 13 of the shell 1 (specifically, the metal sheet 91 can be positioned on the annular surface 13 of the shell 1 through inlaying). In order to more conveniently position the portion of the flexible printed circuit board 46 where the driving element and the current input interface 48 are mounted, at least one positioning hole 910 is further formed in a surface of the metal sheet 91, and correspondingly, a positioning protrusion adapted to the positioning hole 910 is provided on the annular surface 13 of the shell 1.

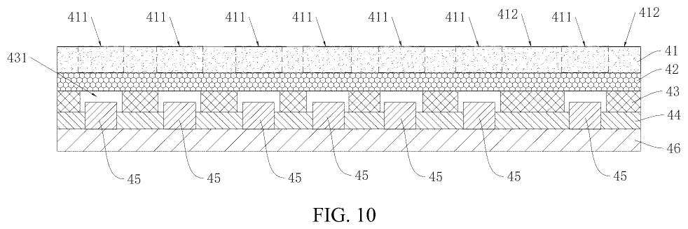

Reference is made to FIG. 10. In some optional embodiments of the present application, the flexible display module 4 further includes a flexible diffusion film 42, where the flexible diffusion film 42 is sandwiched between the flexible display film 41 and the flexible printed circuit board 46, and the flexible diffusion film 42 covers the light-transmitting regions 411 and the light-emitting elements 45. In this embodiment, the flexible diffusion film 42 is provided between the plurality of light-emitting elements 45 and the plurality of light-transmitting regions 411, and on the premise of ensuring that the flexible display module 4 is bendable, the flexible diffusion film 42 can uniformly diffuse the light emitted by the light-emitting elements 45, so that the light emitted by the light-emitting elements 45 can be more uniformly diffused to the light-transmitting regions 411 of the flexible display layer, thereby improving the light display uniformity of the flexible display module 4. During specific implementation, the flexible diffusion film 42 can be a transparent flexible film coated with fluorescent ink (for example, a transparent PET film coated with the fluorescent ink) and can also be other flexible films having a light diffusion function, all that is required is to meet the use requirements, and it is not specifically limited in this embodiment. Optionally, in some implementation manners, the flexible diffusion film 42 is a yellow fluorescent ink film, and the light emitted by the light-emitting elements 45 is blue light. In this embodiment, it should be noted that during specific implementation, the flexible diffusion film 42 and the flexible display film 41 are stacked together in a glue bonding manner, and the flexible diffusion film 42 and the flexible printed circuit board 46 are stacked together in a glue bonding manner.

Reference is continuously made to FIG. 10. In some optional embodiments of the present application, the flexible display module 4 further includes a flexible light-shielding film 43, the flexible light-shielding film 43 is sandwiched between the flexible display film 41 and the flexible printed circuit board 46, a plurality of light-transmitting holes 431 are formed in the flexible light-shielding film 43, and each of the light-transmitting holes 431 is provided opposite to at least one of the light-transmitting regions 411. In this embodiment, through arrangement of the flexible light-shielding film 43, the loss of the light emitted by the light-emitting elements 45 can be reduced on the premise of ensuring that the flexible display module 4 is bendable, so that the light emitted by the light-emitting elements 45 can be more sufficiently transmitted to the light-transmitting regions 411 of the flexible display layer in a concentrated manner, thereby improving the light display effect of the flexible display module 4. During specific implementation, the flexible light-shielding film 43 can be made of an opaque flexible material such as silica gel, rubber and silicone rubber, all that is required is to meet the use requirements, and it is not specifically limited in this embodiment. In this embodiment, it should be noted that during specific implementation, the flexible light-shielding film 43 and the flexible display film 41 are stacked together in a glue bonding manner, and the flexible light-shielding film 43 and the flexible printed circuit board 46 are stacked together in a glue bonding manner.

Reference is continuously made to FIG. 10. In some optional embodiments of the present application, the flexible display module 4 further includes a flexible light-reflecting layer 44, the flexible light-reflecting layer 44 is sandwiched between the flexible display film 41 and the flexible printed circuit board 46, and the light-emitting elements 45 are exposed out of the flexible light-reflecting layer 44. In this embodiment, the arrangement of the flexible light-reflecting layer 44 can improve the light display effect of the flexible display module 4 on the premise of ensuring that the flexible display module 4 is bendable. Specifically, in some use scenes, after the light emitted by the light-emitting elements 45 irradiates the light-transmitting regions 411 of the flexible display film 41, a part of the light will be reflected, and due to the existence of the flexible light-reflecting layer 44, the part of reflected light can be reflected back to the light-transmitting regions 411 of the flexible display film 41 again to a certain extent, thereby increasing the light utilization rate, and enabling the flexible display module 4 to have the better light display effect. During specific implementation, the flexible light-reflecting layer 44 can be a flexible light-reflecting film (such as the transparent polyimide film), can also be a paint layer (optionally, in order to achieve the better light-reflecting effect, the white paint layer can be used as the flexible light-reflecting layer 44), and can also be a light-reflecting ink layer, all that is required is to meet the use requirements, and it is not specifically limited in this embodiment. In this embodiment, it should be noted that during specific implementation, the flexible light-reflecting layer 44 and the flexible display film 41 are stacked together in a glue bonding manner, and the flexible light-reflecting layer 44 and the flexible printed circuit board 46 are stacked together in a glue bonding manner.

It should also be noted here that in the structural design of the flexible display module 4, the flexible diffusion film 42, the flexible light-shielding film 43 and the flexible light-reflecting layer 44 can exist at the same time, or one or two of them can be selected to be provided, which is determined according to the actual use requirements and is not specifically limited in this embodiment. Preferably, in order to obtain the better light display effect, as shown in the drawings, the flexible display film 41, the flexible diffusion film 42, the flexible light-shielding film 43, the flexible light-reflecting layer 44 and the flexible printed circuit board 46 are sequentially stacked, where two adjacent structures can be stacked together in a glue bonding manner.

Reference is made to FIGS. 1-4. In some optional embodiments, the aerosol generation apparatus further includes an annular protective shell 7 made of a light-transmitting material (the light-transmitting material such as glass and acrylic), where the annular protective shell 7 is sleeved on the annular surface 13 of the shell 1, and the flexible display module 4 is located between the annular protective shell 7 and the annular surface 13 of the shell 1. In this embodiment, through arrangement of the annular protective shell 7, it is ensured that the user can observe the light information displayed by the flexible display module 4 through the annular protective shell 7, the flexible display module 4 can be protected, and the flexible display module 4 is prevented from being damaged due to impacts by an external object.

Further, reference is made to FIGS. 1-7. In some optional embodiments, the annular surface 13 of the shell 1 is provided with an annular mounting groove 130 provided in a 360-degree surrounding manner in the circumferential direction of the shell 1, the annular protective shell 7 is adaptively mounted at the annular mounting groove 130, and the flexible display module 4 is provided in the annular mounting groove 130 in a 360-degree surrounding manner in the circumferential direction of the shell 1. In this embodiment, through arrangement of the annular mounting groove 130, on one hand, a certain limiting effect can be achieved for mounting of the flexible display module 4 in the height direction of the shell 1, thereby improving the mounting convenience of the flexible display module 4; on the other hand, the annular protective shell 7 can be accommodated, thereby avoiding the influence on the overall appearance attractiveness of the aerosol generation apparatus due to the fact that the annular protective shell 7 excessively protrudes out of the annular surface 13 of the shell 1.

Reference is made to FIGS. 4-8. In some optional embodiments, in the height direction of the shell 1, the flexible display module 4 has a first edge 401 and a second edge 402 which are opposite to each other, a first notch 4011 is formed in the first edge 401, a second notch 4021 is formed in the second edge 402, a first protrusion 101 adapted to the first notch 4011 and a second protrusion 102 adapted to the second notch 4021 are provided on a groove wall of the annular mounting groove 130 in a protruding manner, at least a part of the first protrusion 101 is located in the first notch 4011, and at least a part of the second protrusion 102 is located in the second notch 4021. In this embodiment, in the process of mounting the flexible display module 4 in the annular groove of the shell 1 in the surrounding manner, after the first protrusion 101 is placed into the first notch 4011 and the second protrusion is placed into the second notch 4021, the first protrusion 101 and the second protrusion 102 can jointly limit the flexible display module 4, so that it is difficult for the flexible display module 4 to move in the height direction of the shell 1 and to move in the circumferential direction of the shell 1, and the flexible display module 4 can be quickly and orderly mounted in the annular groove of the shell 1 in the surrounding manner. It should be noted here that during specific implementation, there may be one or more first notches 4011 and second notches 4021, which can be determined according to the actual use requirements and are not specifically limited in this embodiment.

Reference is made to FIGS. 1-8. In some optional embodiments of the present application, the shell 1 includes a body shell 10 having a hollow interior, a bottom cover 11 having the first end surface 110, and a top cover 12 having the second end surface 120; one end of the body shell 10 in a height direction thereof is fixedly matched with (such as in interference fit or snap-fit connection with) one side of the top cover 12 facing away from the second end surface 120, one end of the body shell 10 facing away from the top cover 12 is fixedly matched with (such as in interference fit or snap-fit connection with) one side of the bottom cover 11 facing away from the first end surface 110, the top cover 12, the body shell 10 and the bottom cover 11 jointly define the annular mounting groove 130, the annular protective shell 7 is sandwiched between the top cover 12 and the bottom cover 11, and the flexible display module 4 surrounds the body shell 10 and is located between the annular protective shell 7 and the body shell 10.

In this embodiment, on the basis of the above structural design, the shell 1 is configured to be of an assembled structure, so that in the process of manufacturing the aerosol generation apparatus, the assembly convenience of the aerosol generation apparatus can be improved. For example, during manufacturing of the aerosol generation apparatus, components such as the control circuit board 32, the gas flow sensor 83 and the charging interface 82 are first mounted in the bottom cover 11; then the bottom cover 11 is adaptively fixed to one port of the body shell 10; next, structures such as the power supply 31, the atomization core 2, components for forming the accommodating compartment 6 and components for forming the gas flow passage 5 are mounted in the body shell 10; then the flexible display module 4 is mounted on a surface of the body shell 10 in a surrounding manner, and the flexible display module 4 is electrically connected to the control circuit board 32 by means of the flexible flat cable 92; then the annular protective shell 7 is sleeved on an outer side of the body shell 10, so that the annular protective shell 7 surrounds the body shell 10; and finally, the top cover 12 where the suction nozzle 81 is mounted is adaptively fixed to the other port of the body shell 10, so that the annular protective shell 7 is sandwiched between the top cover 12 and the bottom cover 11, and the complete aerosol generation apparatus can be obtained.

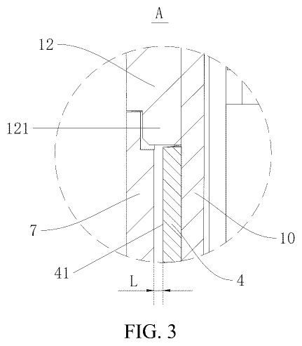

Reference is made to FIGS. 1-4. In some optional embodiments of the present application, a first annular fence portion 111 is provided in a protruding manner on one side of the bottom cover 11 facing away from the first end surface 110, the first annular fence portion 111 is sleeved on an outer wall of one end of the body shell 10 facing away from the top cover 12, a second annular fence portion 121 is provided in a protruding manner on one side of the top cover 12 facing away from the second end surface 120, the second annular fence portion 121 is sleeved on an outer wall of one end of the body shell 10 facing away from the bottom cover 11, one end of the annular protective shell 7 is sleeved on an outer wall of the first annular fence portion 111 and abuts against the bottom cover 11, and one end of the annular protective shell 7 facing away from the bottom cover 11 is sleeved on an outer wall of the second annular fence portion 121 and abuts against the top cover 12. In this embodiment, through arrangement of the first annular fence portion 111 and the second annular fence portion 121, a certain gap exists between an inner surface of the annular protective shell 7 and the flexible display film 41 of the flexible display module 4, so that after the annular protective shell 7 is mounted, damage to the flexible display module 4 due to strong extrusion of the flexible display module 4 by the inner surface of the annular protective shell 7 can be avoided. Preferably, the gap between the inner surface of the annular protective shell 7 and the flexible display film 41 of the flexible display module 4 is 0.1-0.5 mm; and as shown in FIG. 3, assuming that the gap between the inner surface of the annular protective shell 7 and the flexible display film 41 of the flexible display module 4 is L, 0.1 mm≤L≤0.5 mm. Through such arrangement, in some application scenes, even if the entire flexible display module 4 tends to be expanded outwards due to the unreliable bonding between the flexible printed circuit board 46 and the body shell 10, the narrow gap L can effectively prevent the influence on the light display effect shown by the flexible display module 4 to the outside due to a large gap (such as the gap larger than 0.5 mm, which is macroscopically and specifically shown in such a manner that the flexible display module 4 will be changed into, for example, a “C”-shaped open-loop structure from, for example, an “O”-shaped closed-loop structure) between two ends of the flexible display module 4 in the bending length direction thereof due to the fact that the flexible display module 4 is excessively expanded outwards, that is, even if the unreliable bonding occurs between the flexible printed circuit board 46 and the body shell 10, the entire flexible display module 4 can still be stably limited in a narrow space between the inner surface of the annular protective shell 7 and the outer surface of the body shell 10 without great shape changes.

In addition, it should be noted that other contents of the aerosol generation apparatus disclosed in the present application can refer to the prior art and are not repeated here.

The above are only the preferred embodiments of the present application, and do not limit the scope of the patent of the present application. Any equivalent structural transformation made under the utility model concept of the present application by using the contents of the description and the accompanying drawings of the present application, or direct/indirect application in other relevant technical fields, is included in the scope of protection of the patent of the present application.

What is claimed is:

1. An aerosol generation apparatus, comprising:
a shell which is internally provided with a gas flow passage and an accommodating compartment for accommodating an aerosol forming substance;
an atomization core which is mounted on a gas flow circulation path of the gas flow passage and is in communication with the accommodating compartment;
an electric control assembly which is mounted in the shell and is electrically connected to the atomization core; and
a bendable flexible display module which is electrically connected to the electric control assembly, wherein the flexible display module is provided 360 degrees around the shell in a circumferential direction of the shell to cover a plurality of outer surfaces of the shell at different positions.

2. The aerosol generation apparatus according to claim 1, wherein the shell has a first end surface and a second end surface which are opposite to each other in a height direction thereof, the shell has an annular surface located between the first end surface and the second end surface in a circumferential direction thereof, the flexible display module is provided on the annular surface in a 360-degree surrounding manner in the circumferential direction of the shell, the annular surface comprises a plurality of side surfaces sequentially connected end-to-end into a whole in the circumferential direction of the shell, and a joint between the two adjacent side surfaces is in smooth transition.

3. The aerosol generation apparatus according to claim 2, wherein in the height direction of the shell, the flexible display module has a first edge and a second edge which are opposite to each other, a minimum vertical height between the first edge and the second edge is H1, a maximum vertical height between the first edge and the second edge is H2, a vertical height between the first end surface and the second end surface is H3, 0.5H3≤H1≤0.9H3, and 0.5H3≤H2≤0.9H3.

4. The aerosol generation apparatus according to claim 2, wherein the flexible display module comprises a flexible display film, a flexible printed circuit board with a circuit trajectory, and a plurality of light-emitting elements; the flexible printed circuit board is provided on the annular surface in a 360-degree surrounding manner in the circumferential direction of the shell; the plurality of light-emitting elements are distributed at intervals on a side surface of the flexible printed circuit board facing away from the annular surface and are electrically connected to the circuit trajectory; the circuit trajectory is electrically connected to the electric control assembly; and the flexible display film is fixedly stacked on the side surface of the flexible printed circuit board facing away from the annular surface and covers the light-emitting elements, the flexible display film has a plurality of light-transmitting regions, each of the light-transmitting regions is provided opposite to at least one of the light-emitting elements, and a region of the flexible display film apart from the light-transmitting regions is a light-shielding region.

5. The aerosol generation apparatus according to claim 4, further comprising an annular protective shell made of a light-transmitting material, wherein the annular protective shell is sleeved on the annular surface, and the flexible display module is located between the annular protective shell and the annular surface.

6. The aerosol generation apparatus according to claim 5, wherein the annular surface is provided with an annular mounting groove provided in a 360-degree surrounding manner in the circumferential direction of the shell, the annular protective shell is adaptively mounted at the annular mounting groove, and the flexible display module is provided in the annular mounting groove in a 360-degree surrounding manner in the circumferential direction of the shell.

7. The aerosol generation apparatus according to claim 6, wherein in the height direction of the shell, the flexible display module has a first edge and a second edge which are opposite to each other, a first notch is formed in the first edge, a second notch is formed in the second edge, a first protrusion adapted to the first notch and a second protrusion adapted to the second notch are provided on a groove wall of the annular mounting groove in a protruding manner, at least a part of the first protrusion is located in the first notch, and at least a part of the second protrusion is located in the second notch.

8. The aerosol generation apparatus according to claim 6, wherein the shell comprises a body shell having a hollow interior, a bottom cover having the first end surface, and a top cover having the second end surface; one end of the body shell in a height direction thereof is fixedly matched with one side of the top cover facing away from the second end surface, one end of the body shell facing away from the top cover is fixedly matched with one side of the bottom cover facing away from the first end surface, the top cover, the body shell and the bottom cover jointly define the annular mounting groove, the annular protective shell is sandwiched between the top cover and the bottom cover, and the flexible display module surrounds the body shell and is located between the annular protective shell and the body shell.

9. The aerosol generation apparatus according to claim 8, wherein a first annular fence portion is provided in a protruding manner on one side of the bottom cover facing away from the first end surface, the first annular fence portion is sleeved on an outer wall of one end of the body shell facing away from the top cover, a second annular fence portion is provided in a protruding manner on one side of the top cover facing away from the second end surface, the second annular fence portion is sleeved on an outer wall of one end of the body shell facing away from the bottom cover, one end of the annular protective shell is sleeved on an outer wall of the first annular fence portion and abuts against the bottom cover, and one end of the annular protective shell facing away from the bottom cover is sleeved on an outer wall of the second annular fence portion and abuts against the top cover.

10. The aerosol generation apparatus according to claim 9, wherein there is a gap between an inner surface of the annular protective shell and the flexible display film, and the size of the gap is 0.1-0.5 mm.

11. The aerosol generation apparatus according to claim 4, wherein the flexible display module further comprises a current driving element and a current input interface, a side surface of the flexible printed circuit board facing the flexible display film has a first mounting region and a second mounting region which are connected to each other, the area of the first mounting region is greater than that of the second mounting region, a third notch is formed in an edge of the flexible display module, a portion of the flexible printed circuit board provided with the second mounting region is located in the third notch, the plurality of light-emitting elements are fixed in the first mounting region, and the current driving element and the current input interface are mounted in the second mounting region at an interval and are electrically connected to the circuit trajectory.

12. The aerosol generation apparatus according to claim 11, further comprising a metal sheet, wherein the metal sheet is fixed to one side of the flexible printed circuit board facing away from the second mounting region.

13. The aerosol generation apparatus according to claim 11, further comprising a flexible flat cable, wherein one end of the flexible flat cable is inserted into the current input interface, and the other end of the flexible flat cable is inserted into the electric control assembly.

14. The aerosol generation apparatus according to claim 4, wherein the flexible display module further comprises a flexible diffusion film, the flexible diffusion film is sandwiched between the flexible display film and the flexible printed circuit board, and the flexible diffusion film covers the light-transmitting regions and the light-emitting elements.

15. The aerosol generation apparatus according to claim 4, wherein the flexible display module further comprises a flexible light-shielding film, the flexible light-shielding film is sandwiched between the flexible display film and the flexible printed circuit board, a plurality of light-transmitting holes are formed in the flexible light-shielding film, and each of the light-transmitting holes is provided opposite to at least one of the light-transmitting regions.

16. The aerosol generation apparatus according to claim 4, wherein the flexible display module further comprises a flexible light-reflecting layer, the flexible light-reflecting layer is sandwiched between the flexible display film and the flexible printed circuit board, and the light-emitting elements are exposed out of the flexible light-reflecting layer.

17. The aerosol generation apparatus according to claim 4, wherein the electric control assembly comprises a power supply and a control circuit board, and the control circuit board is respectively electrically connected to the power supply, the atomization core and the circuit trajectory.

18. The aerosol generation apparatus according to claim 2, further comprising a suction nozzle provided on the second end surface in a protruding manner, wherein the gas flow passage has a gas inlet and a gas outlet, the gas inlet is provided on the first end surface, and the gas outlet is in communication with the suction nozzle.

19. The aerosol generation apparatus according to claim 2, further comprising a charging interface provided on the first end surface, wherein the charging interface is electrically connected to the electric control assembly.

20. The aerosol generation apparatus according to claim 1, further comprising a gas flow sensor electrically connected to the electric control assembly, wherein the gas flow sensor is located on the gas flow circulation path of the gas flow passage; and the electric control assembly is configured to respond to a suction signal sent by the gas flow sensor to control the atomization core to be electrified to work and to control the flexible display module to display preset information.
